(19) United States
(12) Patent Application Publication
(10) Pub. No.: US 2004/0027185 A1
(43) Pub. Date: Feb. 12, 2004

(54) High-speed differential sampling flip-flop

(76) Inventor: Alan Fiedler, Bloomington, MN (US)

Correspondence Address: John F. Klos, Fulbright & Jaworski L.L.P., Suite 4850, 225 South Sixth Street, Minneapolis, MN, 55402, US

(21) Appl. No.: 10/216,007

(22) Filed: Aug. 9, 2002

(51) Int. Cl. H03K 3/356

(52) U.S. Cl. 327/211

(57) ABSTRACT

A high-speed differential sampling flip-flop includes a differential data input, a differential offset control input, a sampling clock input, an output, a sampling latch, and an RS latch. The sampling latch includes a sampling latch reset circuit, a current steering circuit, first and second switches, and a regenerative latch. The sampling latch reset circuit is coupled to a first power supply and the current steering circuit. The current steering circuit has first and second control terminals which are coupled to the differential data input. The first switch is coupled between the current steering circuit and a second power supply. The regenerative latch is coupled to the current steering circuit, the second switch, and a third power supply. The sampling latch also includes first and second offset control current sources coupled to the current steering circuit and the second power supply, and having first and second control terminals coupled to the differential offset control input. The RS latch includes two cross-coupled nand gates and is coupled to the sampling latch and the output. On a transition of the sampling clock input from logic low to logic high, the differential data input is sampled, amplified to a low or high logic level, and transferred to the output. The differential offset control input is used to control the input offset of the sampling flip-flop.

### BACKGROUND OF THE INVENTION

This invention relates to semiconductor integrated circuits and, more particularly, to a high-speed differential sampling flip-flop. Differential sampling flip-flops are used in applications such as A/D converters and clock and data recovery circuits to measure a first analog voltage relative to a second analog voltage and output a logic value (logic 0 or logic 1, for example) based on this measurement. Typically, a logic 0 is output when the first analog voltage is less than the second analog voltage at the time of the transition of a sampling signal, and a logic 1 is output when the first analog voltage is greater than the second analog voltage. This logic value at the sampling flip-flop output is retained until a subsequent transition of the sampling signal. This operation can be viewed as being functionally equivalent to that of a simple d-type flip-flop, but with a differential data input. For some applications, sampling flip-flop performance requirements such as high-speed and low-power operation, low input capacitance, small size, and low input offset can be difficult to simultaneously achieve. This sampling flip-flop includes circuit elements and a circuit topology which facilitate the simultaneous optimization of each of these performance metrics.

### SUMMARY OF THE INVENTION

The high-speed sampling flip-flop of the present invention has a simple topology which contributes to its very high speed operation. The sampling flip-flop includes a differential data input terminal; first, second, and third clock input terminals; a current steering circuit; first and second switches; a regenerative latch; an RS latch; a sampling latch reset circuit; and an output. Additionally, a differential offset control input and first and second offset control current sources provide for the control and reduction of input offset voltage. To reduce sampling flip-flop power, area, and input capacitance, the sizes of the transistors making up the sampling flip-flop can be reduced, however this action can result in a substantial input offset voltage due to mismatches in transistor performance. The inclusion of the differential offset control input provides for the reduction of the input offset voltage which results when very small transistors are used.

### BRIEF DESCRIPTION OF THE DRAWINGS

FIG. 1 is a schematic diagram illustrating a sampling flip-flop of the prior art.

FIG. 2a is a schematic diagram of the sampling flip-flop in accordance with the present invention.

FIG. 2b is a logic timing diagram illustrating the functionality of the sampling flip-flop.

### DETAILED DESCRIPTION OF THE PREFERRED EMBODIMENTS

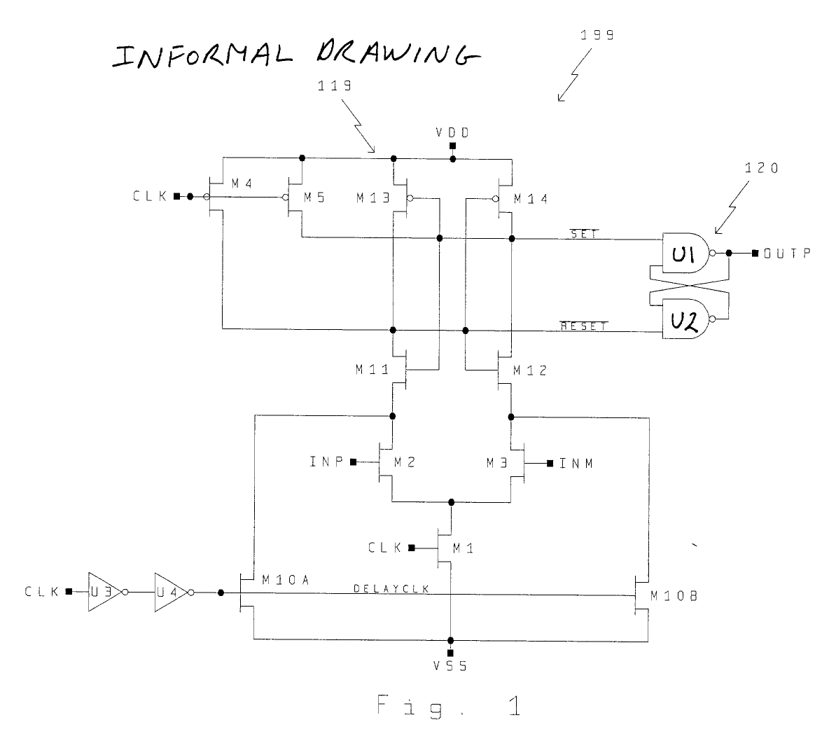

FIG. 1 is a schematic diagram illustrating a sampling flip-flop 199 of the prior art. Sampling flip-flop 199 includes sampling latch 119 and RS latch 120. Prior to sampling, sampling clock CLK is low, reset transistors M4 and M5 are on, /SET and /RESET are pulled high to VDD, and sampling latch 119 is in an initial, balanced state. On a rising edge of CLK, a differential voltage applied to data input terminals INP and INM determines a relative rate at which integration nodes /SET and /RESET are discharged, resulting, over time, in a difference in the voltages on these two nodes. The rising edge of DELAYCLK, delayed from CLK by series inverters U3 and U4, turns on transistors M10A and M10B, thereby enabling the regenerative latch formed by transistors M11, M12, M13, and M14. This regenerative latch amplifies and regenerates the voltage difference between /SET and /RESET. Subsequent to the rising edge of CLK, and if the voltage at INP is more positive than the voltage at INM at the time of the rising edge of CLK, /SET will transition from logic high to logic low, and /RESET will remain substantially at a logic high. Subsequent to the rising edge of CLK, and if the voltage at INM is more positive than the voltage at INP at the time of the CLK transition, /RESET will transition from logic high to logic low, and /SET will remain substantially at a logic high.

RS latch 120 is coupled to /SET, /RESET, and sampling flip-flop 199 output OUT. The logic state of RS latch 120, observed at OUT, is set high by a logic low on /SET, and is set low by a logic low on /RESET. Subsequent to the rising edge of CLK, and after a delay, OUT substantially reflects the relative polarity of data inputs INP and INM at the time of the transition of CLK.

The total capacitive load on /SET and /RESET, as well as the current drive available from transistors coupled to these nodes, determines the bandwidth of the circuit and its maximum operating frequency. It is desirable to minimize this total capacitive load and to maximize the current drive of circuits connected to /SET and /RESET so as to maximize the maximum operating frequency of sampling latch 119. In this sampling latch, the current drive available from transistors M2 and M3 is reduced by series transistors M11 and M12. This reduced current drive results in a reduced sampling latch bandwidth. Additionally, random transistor and capacitive load mismatches will result in a substantial input offset voltage between inputs INP and INM. This sampling latch includes no provision for reduction of this input offset voltage.

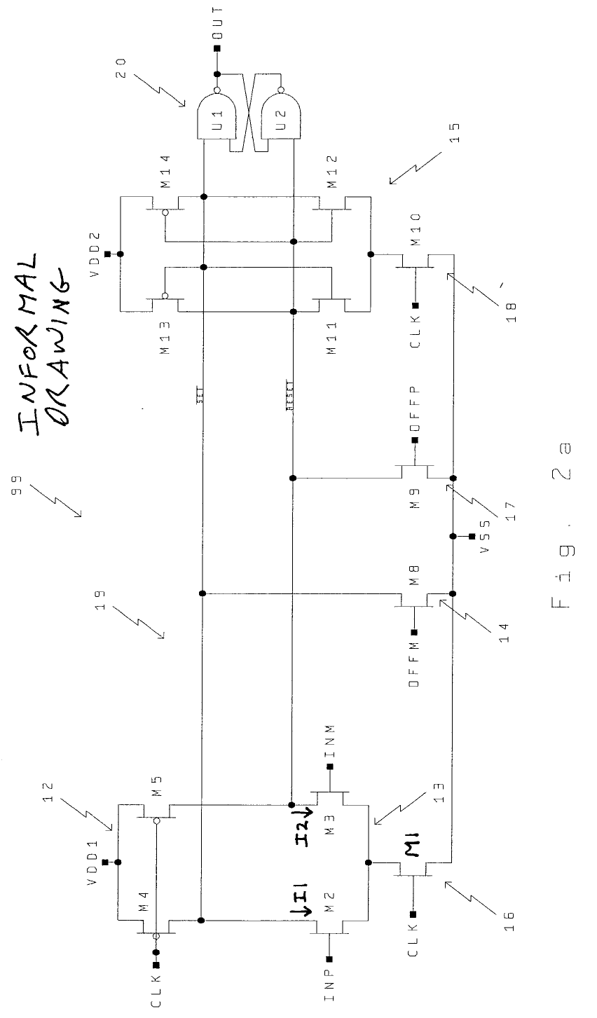

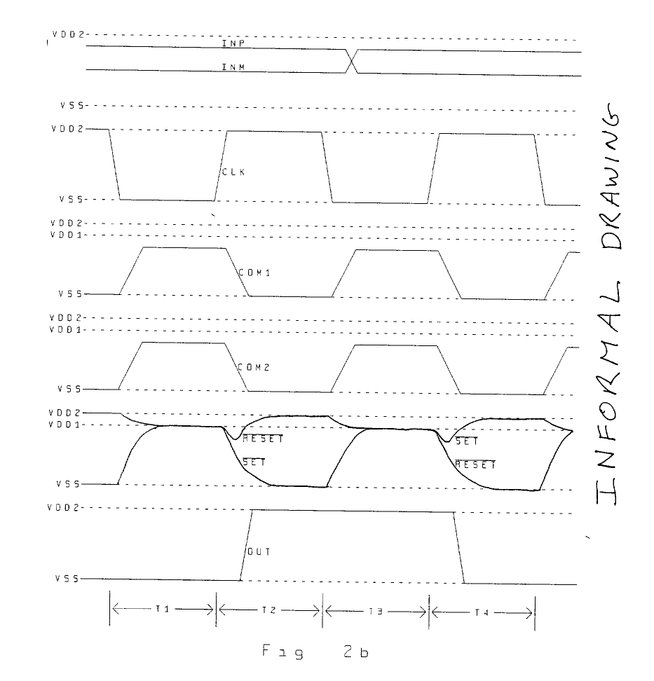

FIG. 2a is a schematic diagram of one embodiment of the sampling flip-flop in accordance with the present invention, and FIG. 2b illustrates its functionality. In FIG. 1 and FIG. 2a, the same or similar reference numerals and designators have been used to indicate elements with similar functions. Sampling latch 19 includes sampling latch reset circuit 12, current steering circuit 13, regenerative latch 15, switches 16 and 18, and first and second offset control current sources 14 and 17. Sampling flip-flop 99 includes sampling latch 19 and RS latch 20.

Sampling latch reset circuit 12 includes PMOS transistor M4 coupled between a first integration node, /SET, and a first power supply terminal, VDD1, and also includes PMOS transistor M5 coupled between a second integration node, /RESET, and VDD1. A gate of M4 and a gate of M5 (each acting as a respective control terminal) are each coupled to a clock input terminal, CLK.

Current steering circuit 13 is coupled to /SET and /RESET, and to first switch 16. Current steering circuit 13 includes NMOS transistors M2 and M3 which control current paths I1 and I2. Transistor M2 is coupled between /SET and a first common node, COM1, and a gate of M2 is coupled to a first data input terminal, INP. Transistor M3 is coupled between /RESET and COM1, and a gate of M3 is coupled to a second data input terminal, INM. Switch 16 includes NMOS transistor M1 coupled between COM1 and a second power supply terminal VSS, and having a gate coupled to CLK. When CLK is a logic high, switch 16 shorts COM1 to VSS, thereby enabling current steering circuit 13.

First offset control current source 14 includes NMOS transistor M8. Transistor M8 has a drain coupled to /SET, a source coupled to VSS, and a gate coupled to a first offset control input terminal OFFM. Second offset control current source 17 includes NMOS transistor M9. Transistor M9 has a drain coupled to /RESET, a source coupled to VSS, and a gate coupled to a second offset control input terminal OFFP. By adjusting the voltage applied to OFFP and to OFFM, the input-referred offset voltage of sampling latch 19 can be adjusted to a low level.

Regenerative latch 15 includes NMOS transistors M11 and M12, and PMOS transistors M13 and M14. Coupled to /RESET are a drain of transistor M11 and a drain of transistor M13, and a gate of transistor M12 and a gate of transistor M14. Coupled to /SET are a drain of transistor M12 and a drain of transistor M14, and a gate of transistor M11 and a gate of transistor M13. A source of transistor M13 and a source of transistor M14 are coupled to a third power supply terminal, VDD2. A source of transistor M11 and a source of transistor M12 is coupled to a common node, COM2. Switch 18 includes NMOS transistor M10 coupled between COM2 and VSS. A gate of M10 is coupled to CLK. When CLK is a logic high, switch 18 shorts COM2 to VSS, thereby enabling regenerative latch 15.

Prior to sampling, CLK is low, reset transistors M4 and M5 are on, /SET and /RESET are pulled high to VDD1, and sampling latch 19 is in an initialized state. On the rising edge of CLK, transistors M1 and M10 turn on, and reset transistors M4 and M5 turn off. Current steering circuit 13, offset control current sources 14 and 17, and regenerative latch 15 each contribute to the discharge of /SET and /RESET towards VSS and at rates relative to each other substantially in proportion to a voltage difference between INP and INM and also in proportion to a voltage difference between OFFP and OFFM. When either /SET discharges sufficiently to turn on PMOS transistor M13 or /RESET discharges sufficiently to turn on PMOS transistor M14, regenerative latch 15 amplifies and regenerates a voltage difference between /SET and /RESET. If /SET discharges more rapidly than /RESET (because INP is more positive than INM, for example), transistor M13 will turn on before transistor M14, and regenerative latch 15 will then rapidly force /SET to a logic low and /RESET to a logic high. If /RESET discharges more rapidly than /SET (because INM is more positive than INP, for example), transistor M14 will turn on before transistor M13, and regenerative latch 15 will then rapidly force /RESET to a logic low and /SET to a logic high. Sampling latch 19 will then reliably hold this state, independent of any change in voltage at INP and INM, until CLK goes low and once again sampling latch 19 is reset to an initialized state.

Integration time, as measured from the rising edge of CLK to the time that either M13 or M14 turn on and regenerative latch 15 activates, can be controlled by a voltage difference between VDD1 and VDD2. If this difference is increased or made more positive, integration time increases, resulting in a lower sampling latch bandwidth and improved noise rejection. If this difference is decreased or made more negative, integration time decreases, resulting in higher sampling latch bandwidth and degraded noise rejection. The ability to control integration time facilitates an effective trade-off between sampling latch bandwidth and noise rejection.

RS latch 20 includes cross-coupled 2-input NAND gates U1 and U2. A first input of NAND gate U1 is coupled to /SET and a second input of NAND gate U1 is coupled to an output of NAND gate U2. A first input of NAND gate U2 is coupled to /RESET and a second input of NAND gate U2 is coupled to an output of NAND gate U1. The output of NAND gate U1 is coupled to sampling flip-flop output terminal OUT. The logic state of RS latch 20, observed at OUT, is set high by a logic low on /SET, and is set low by a logic low on /RESET.

Sampling latch 19 and RS latch 20 combine to form sampling flip-flop 99. Subsequent to a rising edge of CLK, and after a delay, sampling flip-flop output OUT substantially reflects the relative polarity of data inputs INP and INM, and of offset control inputs OFFP and OFFM, at the time of the rising edge of CLK. Offset control inputs OFFP and OFFM can be set such that the input-referred offset voltage of sampling flip-flop 99 is reduced to a low level and so that, for example, when the relative voltage difference between INP and INM is substantially zero at the time of the rising edge of CLK, after a short delay there is statistically a 50% chance of a logic high at OUT, and 50% chance of a logic low.

FIG. 2b illustrates an example of the functionality of sampling flip-flop 99 described above. In time interval T1, CLK is low and sampling latch 19 is reset to an initialized state with both /RESET and /SET asserted to a voltage level substantially equal to VDD1. In time interval T2, CLK transitions from VSS to VDD2 (logic low to logic high) while at the same time the relative voltage difference between INP and INM is positive. This results in /SET discharging to VSS at a faster rate than /RESET at the beginning of time interval T2. During the remainder of time interval T2, regenerative latch 15 amplifies and regenerates the voltage difference between /SET and /RESET, driving /SET to VSS and /RESET to VDD2, and this state is stably held, regardless of any change in the voltage difference between INP and INM. Finally, and in response to the logic low on /SET during time interval T2, the output terminal of RS latch 20 (and thereby of sampling flip-flop 99) transitions from logic low to logic high.

Sampling flip-flop operation during time intervals T3 and T4 is substantially the same as that during time intervals T1 and T2, except for the following differences: the relative voltage difference between INP and INM is negative, /RESET discharges at a faster rate than /SET, /RESET is driven to VSS and /SET is driven to VDD2, and the output terminal of RS latch 20 (and thereby sampling flip-flop 99) transitions from logic high to logic low.

In an alternative embodiment, each of the following clock input terminals may be coupled to different clock input signals: the clock input terminal associated with M4 and M5, the clock input terminal associated with M10, and the clock input terminal associated with M1.

Although the present invention has been described with reference to preferred embodiments, workers skilled in the art will recognize that changes may be made in form and detail without departing from the spirit and scope of the invention. Many of the components of the sampling flip-flop can be implemented with a variety of components and in a variety of configurations. The sampling flip-flop can be implemented with discreet components, with semiconductor devices embedded in an integrated circuit such as an application specific integrated circuit (ASIC), or with a combination of both. Except to the extent specified within the following claims, the circuit configurations shown herein are provided as examples only.

Individual signals or devices can be active high or low, and corresponding circuitry can be converted or complemented to suit any particular convention. The term “coupled” used in the specification and in the claims includes various types of connections or couplings and includes a direct connection or a connection through one or more intermediate components.

What is claimed is:

1. A sampling flip-flop comprising:
first and second data input terminals;
first, second, and third clock input terminals;
an output terminal;
first, second, and third power supply terminals;
a first switch coupled between a first integration node and the first power supply terminal and having a control terminal coupled to the first clock input terminal;
a second switch coupled between a second integration node and the first power supply terminal and having a control terminal coupled to the first clock input terminal;
a current steering circuit having first and second data input terminals which control current through first and second current paths, coupled to the first and second integration nodes and a first common node;
a third switch coupled between the first common node and the second power supply terminal and having a control terminal coupled to the second clock input terminal;
a first latch circuit coupled to the first and second integration nodes, the third power supply terminal, and a second common node;
a fourth switch coupled between the second common node and the second power supply terminal and having a control terminal coupled to the third clock input terminal; and
a second latch circuit coupled between the first and second integration nodes and the output terminal.

2. The sampling flip-flop of claim 1 and further comprising:
first and second offset control input terminals;
a first current source coupled between the first integration node and the second power supply, and having a control terminal coupled to the first offset control input terminal; and
a second current source coupled between the second integration node and the second power supply terminal, and having a control terminal coupled to the second offset control input terminal.

3. The sampling flip-flop of claim 1, wherein the first, second, third, and fourth switches each comprise a transistor having a drain and a source, and a gate coupled to the control terminal.

4. The sampling flip-flop of claim 1 wherein the current steering circuit comprises:
a first transistor coupled between the first integration node and the first common node, and having a control terminal coupled to the first data input terminal;
a second transistor coupled between the second integration node and the first common node, and having a control terminal coupled to the second data input terminal.

5. The sampling flip-flop of claim 1 wherein the first latch circuit comprises:
a first transistor coupled between the first integration node and the second common node, and having a control terminal coupled to the second integration node;
a second transistor coupled between the second integration node and the second common node and having a control terminal coupled to the first integration node;
a third transistor coupled between the first integration node and the third power supply terminal and having a control terminal coupled to the second integration node; and
a fourth transistor coupled between the second integration node and the third power supply terminal and having a control terminal coupled to the first integration node.

6. The sampling flip-flop of claim 1 wherein the second latch circuit comprises:
a first nand logic gate with a first logic input, and having a second logic input coupled to the first integration node and a logic output coupled to the output terminal; and
a second nand logic gate with a first logic input coupled to the output terminal, a second logic input coupled to the second integration node, and a logic output coupled to the first logic input of the first nand logic gate.

7. The sampling flip-flop of claim 1, further comprising a clock input signal coupled to the first, second, and third clock input terminals.

8. The sampling flip-flop of claim 1, further comprising:
a first power supply voltage applied to the first and third power supply terminals; and
a second power supply voltage applied to the second power supply terminal.

9. The sampling flip-flop of claim 1, further comprising:
a first power supply voltage applied to the first power supply terminal;
a second power supply voltage applied to the third power supply terminal; and
means to adjust the first power supply voltage relative to the second power supply voltage so as to adjust the sampling flip-flop bandwidth and noise rejection.

10. A sampling flip-flop comprising:
first and second data input terminals for receiving a differential data signal;
first and second offset control input terminals for receiving first and second offset control signals;
a clock input terminal for receiving a clock signal;
a logic output terminal for transmitting an output signal;
steering means, coupled to the first and second data input terminals, for steering first and second currents through first and second current paths as a function of the differential data signal;
first switch means, coupled to the steering means and to the clock input terminal, for supplying a current to the first and second current paths as a function of the clock signal;
second switch means, coupled to the steering means and to the clock input terminal, for resetting the sampling flip-flop to an initialized state;
first current source means, coupled to the first offset control input terminal, for conducting a third current;
second current source means, coupled to the second offset control input terminal, for conducting a fourth current;
latch means, coupled to the steering means, for generating an output signal as a function of the first, second, third, and fourth currents; and
third switch means coupled to the latch means for the purpose of controlling a regenerative state of the latch means.

11. The sampling flip-flop of claim 10 wherein the output signal, subsequent to a transition of the clock signal, substantially reflects the polarity of the differential data signal at the time of the transition of the clock signal.
